(19) United States
(12) Patent Application Publication
(10) Pub. No.: US 2014/0320841 A1
(43) Pub. Date: Oct. 30, 2014

(54) HOLDING APPARATUS, PROCESSING APPARATUS, AND METHOD OF MANUFACTURING ARTICLE

(71) Applicant: CANON KABUSHIKI KAISHA, Tokyo (JP)

(72) Inventors: Masato MURAKI, Inagi-shi (JP); Hiroshi KII, Utsunomiya-shi (JP)

(73) Assignee: CANON KABUSHIKI KAISHA, Tokyo (JP)

(21) Appl. No.: 14/244,436

(22) Filed: Apr. 3, 2014

(30) Foreign Application Priority Data
Apr. 25, 2013 (JP) 2013-093052

(51) Int. Cl. G03F 7/20

(52) U.S. Cl. CPC G03F 7/70708
USPC 355/73; 355/77

(57) ABSTRACT

The present invention provides a holding apparatus for holding a substrate by an electrostatic force, the apparatus including a base including an electrode for generating the electrostatic force, a plurality of pins provided on the base, and a seal provided on the base and configured to seal a first space surrounding the plurality of pins, wherein a cavity and a first hole connecting the cavity and the first space is formed in the base, wherein a gas is sealed in the first space, the first hole and the cavity in a vacuum by holding the substrate on the pins and the seal by the electrostatic force.

### BACKGROUND OF THE INVENTION

1. Field of the Invention

The present invention relates to a holding apparatus which holds a substrate, a processing apparatus, and a method of manufacturing an article.

2. Description of the Related Art

Various kinds of substrate holding members which hold substrates such as silicon wafers are used in semiconductor device manufacturing processes. The pattern image qualities such as flatness of a substrate (exposure surface) to be held and less deformation of a substrate which causes the misalignment of a pattern image must be considered for the substrate holding members.

As one of the substrate holding members, a chuck (electrostatic chuck) for holding a substrate by an electrostatic force is available. Such a substrate holding member can perform a process on the entire surface of the substrate. In addition, the substrate holding member can effectively be used under a high vacuum environment. A typical electrostatic chuck includes a holding surface for holding a substrate and an electrostatic member which is electrostatically biased with respect to the substrate by an electrical potential. The substrate is held at a predetermined position with respect to the holding surface by the electrostatic force.

Heat may be generated in the substrate during the substrate process. For this reason, it is important to limit the temperature rise of the substrate and maintain the temperature uniformity on the substrate surface. This is because substrate deformation (thermal deformation) may occur when there is an excess temperature distribution (for example, temperature distribution due to nonuniform heat transfer) on the substrate surface. Note that heat transfer from the substrate to the chuck is not efficient under a vacuum environment.

Furthermore, fine particles are sandwiched between the chuck and the substrate to deform the substrate. For this reason, a pin chuck constituted by a plurality of pins is generally used as the chuck for holding the substrate. Consequently, it is difficult to achieve good contact between the chuck and the substrate, and the temperature uniformity on the substrate surface cannot be maintained because of the further reduction in heat transfer efficiency. The pattern image qualities deteriorate due to substrate deformation.

Hence, as proposed in the case of a CVD (Chemical Vapor Deposition) apparatus, supplying an inert gas such as helium between the chuck and the substrate to exhaust heat can be considered (see Japanese Patent Laid-Open No. 2002-305238).

However, the technique in Japanese Patent Laid-Open No. 2002-305238 does not consider movement of a chuck which holds the substrate. On the other hand, in an exposure apparatus, the chuck which holds the substrate is placed on a stage, and this stage moves according to an exposure process. Therefore, when applying the technique in Japanese Patent Laid-Open No. 2002-305238 to the exposure apparatus, the stage ends up dragging a pipe which supplies the inert gas to be supplied between the chuck and the substrate, and this influences the stage movement. Hence, this technique is impractical.

### SUMMARY OF THE INVENTION

The present invention provides, for example, a holding apparatus advantageous in moving thereof together with a stage.

According to one aspect of the present invention, there is provided a holding apparatus for holding a substrate by an electrostatic force, the apparatus comprising: a base including an electrode for generating the electrostatic force; a plurality of pins provided on the base; and a seal provided on the base and configured to seal a first space surrounding the plurality of pins, wherein a cavity and a first hole connecting the cavity and the first space is formed in the base, wherein a gas is sealed in the first space, the first hole and the cavity in a vacuum by holding the substrate on the pins and the seal by the electrostatic force.

Further aspects of the present invention will become apparent from the following description of exemplary embodiments with reference to the attached drawings.

### BRIEF DESCRIPTION OF THE DRAWINGS

FIG. 1 is a schematic plan view showing a holding member according to an aspect of the present invention.

FIG. 2 is a schematic sectional view showing the holding member according to an aspect of the present invention.

FIG. 3 is a schematic view showing the arrangement of a processing apparatus according to an aspect of the present invention.

FIG. 4 is a schematic sectional view showing the holding member according to an aspect of the present invention.

FIG. 5 is a schematic sectional view showing the holding member according to an aspect of the present invention.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

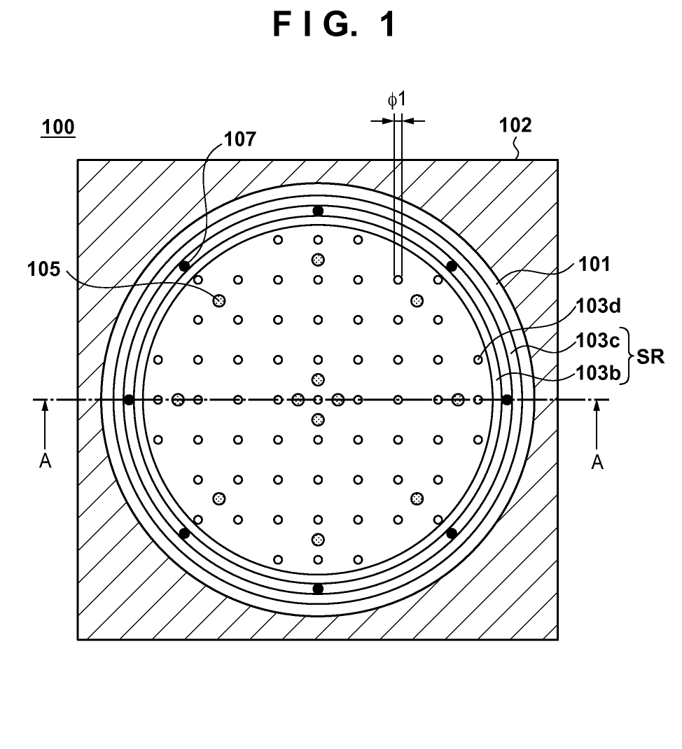

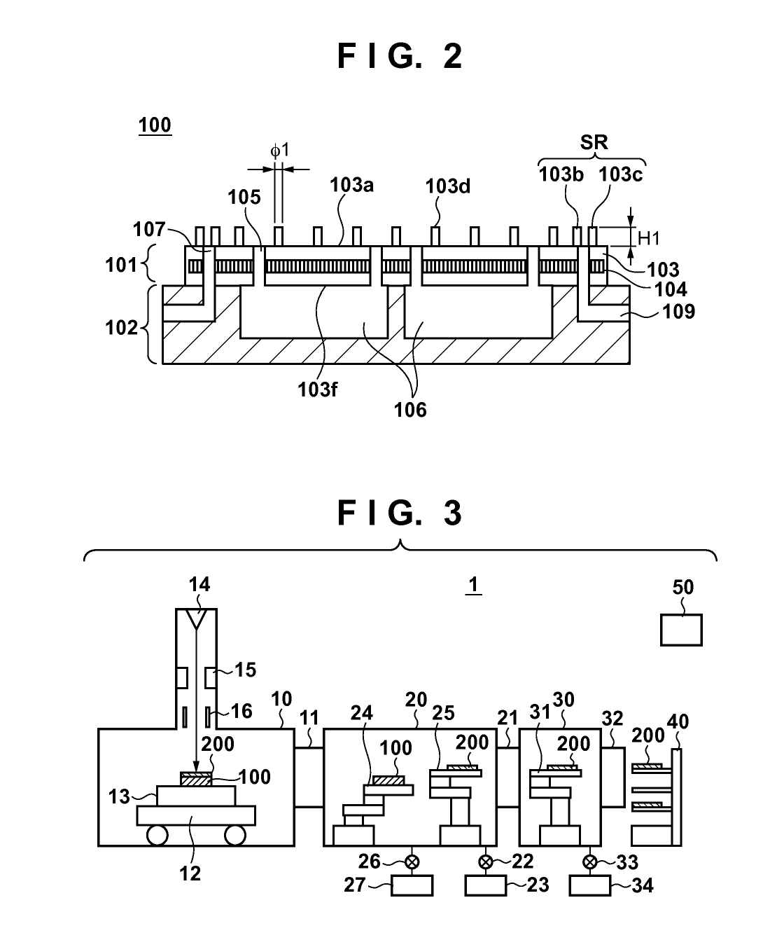

FIG. 1 is a schematic plan view showing a holding member (holding apparatus) 100 according to an aspect of the present invention. FIG. 2 is a schematic sectional view taken along a line A-A of the holding member 100 shown in FIG. 1. The holding member 100 is a pallet which is carried while holding a substrate by an electrostatic force. The holding member 100 includes an electrostatic chuck 101 for holding the substrate and a base plate 102 for supporting the electrostatic chuck 101. In this embodiment, the electrostatic chuck 101 and the base plate 102 constitute the base of the holding member 100.

The electrostatic chuck 101 is a Coulomb type electrostatic chuck, which includes a base 103 and an electrostatic electrode 104 for generating an electrostatic force. The base 103 is made of a ceramic material and fixed on the base plate 102 through an adhesion layer. In other words, the base plate 102 supports the electrostatic chuck 101 from a lower surface 103f side which is opposite to an upper surface 103a on a substrate side of the electrostatic chuck 101. Furthermore, a dielectric layer is formed on a lower surface (an opposite surface to an upper surface on the base side) of the base plate 102.

A plurality of holding pins 103d are formed to be scattered in a matrix on the upper surface 103a of the electrostatic chuck 101. The plurality of holding pins 103d are, for example, constituted by columnar protrusions which contact the substrate, and serve to support and hold the substrate. Furthermore, on the upper surface 103a of the electrostatic chuck 101, and more specifically in its outer edge portion, a peripheral seal ring (sealing unit) SR for sealing a space between the upper surface 103a of the electrostatic chuck 101 and the substrate by contacting the substrate is formed to surround the plurality of holding pins 103d. The peripheral seal ring SR is constituted by an annular protrusion and seals a first space which surrounds the plurality of holding pins 103d. In this embodiment, the peripheral seal ring SR includes an inner seal ring (first sealing unit) 103b and an outer seal ring (second sealing unit) 103c which surrounds the inner seal ring 103b (that is, outside the inner seal ring 103b).

The inner seal ring 103b, the outer seal ring 103c, and the holding pins 103d have the same height H1. The height H1 of the inner seal ring 103b, the outer seal ring 103c, and the holding pins 103d is, for example, set in the range of 5 to 40 μm. In addition, the diameter φ1 of the holding pins 103d is, for example, set in the range of 1.0 to 2.0 mm.

The electrostatic electrode 104 is a thin film electrostatic electrode, and incorporated in the base 103. The electrostatic electrode 104 is connected to an external DC power supply (not shown). When a predetermined voltage is applied to the electrostatic electrode 104, a holding target such as a substrate is attracted to the inner seal ring 103b, the outer seal ring 103c, and the holding pins 103d. An attraction force for the holding target increases as a higher voltage is applied to the electrostatic electrode 104.

First through holes 105 extending through the base 103 (electrostatic chuck 101) are formed in the base 103. The first through holes 105 are connected to a gas reservoir 106 formed in the base plate 102. The gas reservoir 106 is a cavity connected to a space (that is, the first space) between the upper surface 103a of the electrostatic chuck 101 and the substrate through the first through holes 105 to store gas, such as an inert gas, filled (trapped) in this space. In this way, the first through holes 105 allows the gas reservoir 106 and the first space to communicate with each other. Also, the gas reservoir 106 communicates with an external space through only the first through holes 105.

Furthermore, second through holes 107, which extend through the base 103 (electrostatic chuck 101) in an area between the inner seal ring 103b and the outer seal ring 103c, are formed in the base 103. The second through holes 107 are connected to connection paths 109 formed in the base plate 102. The connection paths 109 connect the second through holes 107 and the external space. Therefore, the second through holes 107 and the connection paths 109 allow the second space between the inner seal ring 103b and the outer seal ring 103c, and the external space to communicate with each other.

In this arrangement, in a vacuum, the holding member 100 holds the substrate by the inner seal ring 103b, the outer seal ring 103c, and the holding pins 103d after the state in which the upper surface 103a of the electrostatic chuck 101 is exposed. This traps (seals) a gas within a closed space which includes the first through holes 105 and the gas reservoir 106, in the space (that is, the first space) between the upper surface 103a of the electrostatic chuck 101 and the substrate, and this closed space, thereby improving thermal conductivity between the electrostatic chuck 101 and the substrate.

A processing apparatus 1 according to an aspect of the present invention will be described with reference to FIG. 3. The processing apparatus 1 is a vacuum processing apparatus, which carries a substrate by the holding member 100 and processes this substrate in a vacuum. The processing apparatus 1 includes a processing chamber 10, gate valve 11, substrate stage 12, electrostatic chuck 13, charged particle source 14, electromagnetic deflector 15, and electrostatic deflector 16. The processing apparatus 1 also includes an anterior chamber 20, gate valve 21, vacuum valve 22, vacuum pump 23, carrying robot 24, holding robot 25, gas valve 26, and gas source 27. The processing apparatus 1 further includes a load lock chamber 30, substrate carrying robot 31, gate valve 32, vacuum valve 33, vacuum pump 34, and control unit 50. The control unit 50 includes a CPU and memory, and controls the overall (operation of the) processing apparatus 1. The control unit 50 controls not only a process of a substrate 200, that is, a process of drawing (forming) a pattern on the substrate 200 in this embodiment, but also a process for causing the holding member 100 to hold the substrate 200.

The process of the substrate 200 in the processing apparatus 1 will be described. This process is performed by the control unit 50 which comprehensively controls the respective units of the processing apparatus 1. First, the substrate 200 stored in a substrate station 40 arranged on an atmospheric side is carried to the load lock chamber 30 in order to carry the substrate 200 to the anterior chamber 20 by the substrate carrying robot 31. When the substrate 200 is carried to the load lock chamber 30, the gate valve 32, which separates and the load lock chamber 30 from the atmospheric side, is closed to open the vacuum valve 33, and the load lock chamber 30 is evacuated by the vacuum pump 34. Thus, the load lock chamber 30 is used for holding the substrate 200 to be carried to the anterior chamber 20 in a vacuum atmosphere.

Next, the gate valve 21, which separates the load lock chamber 30 from the anterior chamber 20, is opened. The anterior chamber 20 is a vacuum chamber for causing the holding member 100 prepared in the anterior chamber 20 to hold the substrate 200 carried from the load lock chamber 30 (that is, to be carried to the processing chamber 10). The vacuum valve 22 connected to the anterior chamber 20 is open. The anterior chamber 20 is evacuated by the vacuum pump (exhaust device) 23. In addition, the carrying robot 24 for carrying the holding member 100 is arranged in the anterior chamber 20.

When the gate valve 21 is opened, the substrate 200 carried by the substrate carrying robot 31 is placed on the holding robot 25 and the gate valve 21 and the vacuum valve 22 are closed. Then, the gas valve 26 is opened, and the inert gas, helium gas in this embodiment, is supplied from the gas source (supply unit) 27 to the anterior chamber 20. In this case, the gas source 27 can supply the helium gas to the anterior chamber 20 so that a helium gas pressure in the anterior chamber 20 falls within the range of 500 to 5,000 Pa.

When the pressure of the helium gas in the anterior chamber 20 reaches a predetermined pressure, the gas valve 26 is closed. This brings the state in which the upper surface 103a of the electrostatic chuck 101 is exposed in a helium gas atmosphere. The helium gas is filled, through the first through holes 105, in the gas reservoir 106 at almost the same pressure as that of the anterior chamber 20.

Next, the holding robot 25 places the substrate 200 on the holding member 100 held by the carrying robot 24, and applies a voltage to the electrostatic electrode 104 to make the electrostatic chuck 101 attract the substrate 200. Thus the substrate 200 is held by the holding member 100, that is, the inner seal ring 103b, outer seal ring 103c, and the holding pins 103d. Then, the vacuum valve 22 is opened, and the anterior chamber 20 is evacuated by the vacuum pump 23.

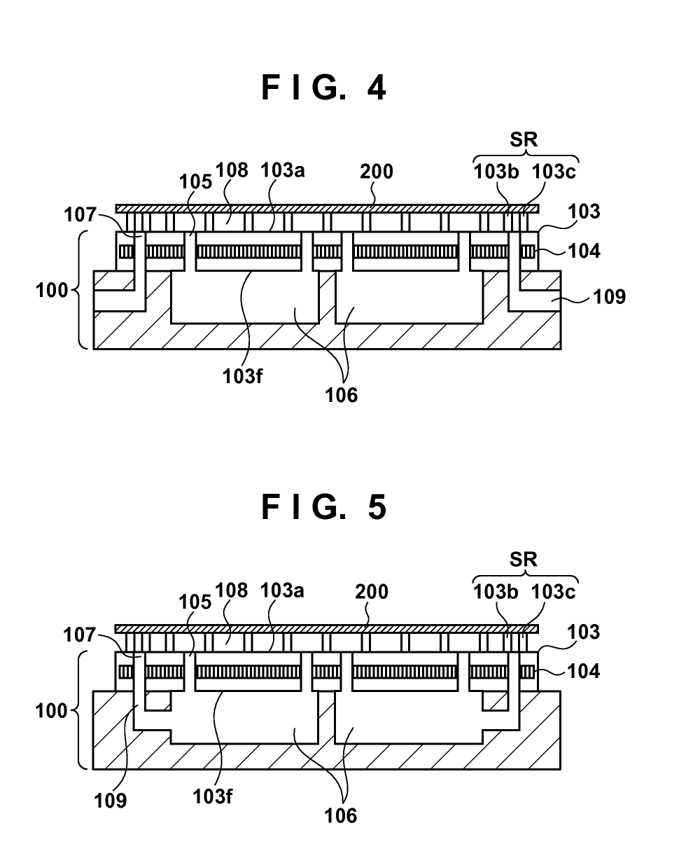

FIG. 4 is a schematic sectional view showing the holding member 100 holding the substrate 200 after the state in which the upper surface 103a of the electrostatic chuck 101 is exposed in the helium gas atmosphere, that is, in the anterior chamber 20. In FIG. 4, an atmosphere external to (around) the holding member 100 is a vacuum. Furthermore, the helium gas is trapped in a space sealed with the peripheral seal ring SR, that is, a space 108 between the upper surface 103a of the electrostatic chuck 101 and the substrate, and the closed space which includes the first through holes 105 and the gas reservoir 106. Here, the space 108 is connected to the gas reservoir 106 through the first through holes 105. Therefore, even if a small amount of helium gas leaks between the substrate 200 and the inner seal ring 103b, it is possible to maintain the uniformity of the helium gas pressure in the space 108 while reducing a pressure fluctuation of the helium gas. This stably improves heat transfer between the substrate 200 and the holding member 100.

Furthermore, the area between the inner seal ring 103b and the outer seal ring 103c is connected to the outside (vacuum atmosphere) through the second through holes 107 and the connection path 109. Therefore, the area of the substrate 200, which contacts the inner seal ring 103b and the outer seal ring 103c, is different from that of the substrate 200 inside the inner seal ring 103b. Both the holding member side (lower surface) and its opposite side (upper surface) are set in an vacuum atmosphere. Hence, a pressure difference between the lower surface and the upper surface does not occur in the area of the substrate 200 which contacts the inner seal ring 103b and the outer seal ring 103c. This makes it possible to prevent the reduction of an attraction force by the holding member 100. This makes it possible to prevent sandwiching fine particles and to increase an attraction force in the area of the substrate 200, which contacts the inner seal ring 103b and the outer seal ring 103c, more than that in the area of the substrate 200 inside the inner seal ring 103b. As a result, it is possible to reduce the leakage of the helium gas by improving the hermeticity of the space 108 (the closed space including the space 108, the first through holes 105, and the gas reservoir 106) between the upper surface 103a of the electrostatic chuck 101 and the substrate.

Referring back to FIG. 3, when the anterior chamber 20 is evacuated, the gate valve 11 which separates the anterior chamber 20 from the processing chamber 10 is opened, and the holding member 100 which holds the substrate 200 is carried to the processing chamber 10 by the carrying robot 24. The processing chamber 10 serves to process the substrate 200 in a vacuum. Then, the holding member 100 carried by the carrying robot 24 is placed in the electrostatic chuck 13 on the substrate stage 12, and attracted (fixed) with the electrostatic chuck 13. Here, the holding member 100 which holds the substrate 200 is evacuated in the processing chamber 10. Note that because the helium gas pressure in the space 108 between the upper surface 103a of the electrostatic chuck 101 and the substrate is about 5,000 Pa, the temperature drop due to the adiabatic expansion of gas can be ignored even when evacuated. As a consequence, the temperature of the holding member 100 needs not be controlled.

When the holding member 100 is attracted to the electrostatic chuck 13, the gate valve 11 is closed. A charged particle optical system which irradiates the substrate 200 held by the holding member 100 with a charged particle beam and performs drawing on the substrate 200 with this charged particle beam is arranged in the processing chamber 10, and always evacuated by an evacuation system (not shown). In other words, the processing chamber 10 includes an irradiation unit for irradiating the substrate 200 held by the holding member 100 with an energy beam to form a pattern on the substrate 200. In this embodiment, the charged particle optical system includes the charged particle source 14, the electromagnetic deflector 15, and the electrostatic deflector 16. A pattern drawing onto the substrate 200 is performed by scanning the charged particle beam from the charged particle source 14 with the electromagnetic deflector 15 and the electrostatic deflector 16, while moving the substrate stage 12.

When the pattern drawing onto the substrate 200 has ended, the holding member 100 which holds the substrate 200 is carried to the anterior chamber 20 by the carrying robot 24, and the gate valve 11 is closed. Next, the substrate 200 is removed from the holding member 100 on the carrying robot 24 by the holding robot 25. Then, the gate valve 21 is opened to carry the substrate 200 on the holding robot 25 to the load lock chamber 30 by the substrate carrying robot 31, and the load lock chamber 30 is released to the atmosphere after closing the gate valve 21. Once the load lock chamber 30 has been released to the atmosphere, the gate valve 32 is opened, and the substrate 200 on which the pattern is formed is carried to the substrate station 40 by the substrate carrying robot 31.

In this way, the processing apparatus 1 uses the holding member 100 to carry and hold the substrate 200. Therefore, it is possible to carry the substrate 200 in a state in which the inert gas is trapped in the space between the upper surface 103a of the electrostatic chuck 101 and the substrate, and the closed space, which includes the first through holes 105 and the gas reservoir 106, without connecting a pipe for supplying the inert gas to the holding member 100. This enables to improve the thermal conductivity between the electrostatic chuck 101 and the substrate, and at the same time to process the substrate 200 without influencing carrying of the holding member 100 and movement of the substrate stage 12. In other words, the processing apparatus 1 can provide an article such as a high quality device economically with high throughput.

Also, the holding member 100 is not limited to the arrangements shown in FIGS. 1, 2, and 4, but may be the arrangement as shown in FIG. 5, for example. In contrast to the holding member 100 shown in FIGS. 1, 2, and 4, the holding member 100 shown in FIG. 5 has a connection path 110 formed in the base plate 102. The connection path 110 connects the second through holes 107 formed in the area between the inner seal ring 103b and the outer seal ring 103c, and the gas reservoir 106. In this way, the second through holes 107 and the connection path 110 extend through the second space between the inner seal ring 103b and the outer seal ring 103c, and the gas reservoir 106.

In this arrangement, the helium gas trapped (shielded) in the space 108 between the upper surface 103a of the electrostatic chuck 101 and the substrate will be doubly sealed by the inner seal ring 103b and the outer seal ring 103c. More strictly, although the gas reservoir 106 is common, the second through holes 107 is formed so that their conductance is made smaller than that of the first through holes 105. Hence, the helium gas will be doubly trapped, practically. As a consequence, it is possible to maintain the uniformity of the helium gas pressure in the space 108 even when the helium gas leaks from the area between the substrate 200 and the inner seal ring 103b. This stably improves the heat transfer between the substrate 200 and the holding member 100.

A method of manufacturing an article according to an embodiment of the present invention is suitable for manufacturing an article, for example, a microdevice such as a semiconductor device or an element having a microstructure. This manufacturing method includes, using the processing apparatus 1, a step of forming a pattern on a substrate on which a photoresist is applied, and a step of processing (for example, developing) the substrate on which the pattern has been formed. Furthermore, this manufacturing method can further include other known steps (oxidation, deposition, evaporation, doping, planarization, etching, resist removal, dicing, bonding, packaging, and the like) after the forming step. The method of manufacturing an article according to this embodiment is advantageous in at least one of the performance, quality, productivity, and production cost of an article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-093052, filed on Apr. 25, 2013, which is hereby incorporated by reference herein in its entirety.

What is claimed is:

1. A holding apparatus for holding a substrate by an electrostatic force, the apparatus comprising:
a base including an electrode for generating the electrostatic force;
a plurality of pins provided on the base; and
a seal provided on the base and configured to seal a first space surrounding the plurality of pins,
wherein a cavity and a first hole connecting the cavity and the first space is formed in the base,
wherein a gas is sealed in the first space, the first hole and the cavity in a vacuum by holding the substrate on the pins and the seal by the electrostatic force.

2. The apparatus according to claim 1, wherein the seal includes a first seal and a second seal outside the first seal.

3. The apparatus according to claim 2, wherein a second hole which connects a second space, between the first seal and the second seal, and an external space is formed in the base.

4. The apparatus according to claim 2, wherein a second hole which connects a second space, between the first seal and the second seal, and the cavity is formed in the base.

5. The apparatus according to claim 4, wherein the second hole is formed such that a conductance of the second hole is smaller than that of the first hole.

6. The apparatus according to claim 1, wherein the cavity is formed to communicate with an external space through only the first hole.

7. The apparatus according to claim 1, wherein the gas includes an inert gas.

8. A processing apparatus for processing a substrate, the apparatus comprising:
a processing chamber in which the substrate is processed in a vacuum;
an anterior chamber in which the holding apparatus, according to claim 1, is caused to hold the substrate to be carried to the processing chamber;
a supply device configured to supply a gas into the anterior chamber; and
a controller configured to control a process for causing the holding apparatus to hold the substrate,
wherein the controller is configured to perform
a first process of supplying the gas into the anterior chamber by the supply device, and
a second process of sealing the gas in the first space, the first hole, and the cavity by holding the substrate on the pins and the seal by the electrostatic force in an atmosphere of the gas.

9. The apparatus according to claim 8, further comprising an exhaust device configured to exhaust the anterior chamber,
wherein the controller is configured to perform, after the second process, a third process of exhausting the anterior chamber by the exhaust device and carrying the holding apparatus which holds the substrate to the processing chamber.

10. The apparatus according to claim 8, wherein the controller is configured to control the supply device in the first process such that a pressure of the gas in the anterior chamber falls within a range of 500 to 5,000 Pa.

11. The apparatus according to claim 8, further comprising a load lock chamber for carrying the substrate to the anterior chamber.

12. The apparatus according to claim 8, wherein the processing chamber includes an irradiation device configured to irradiate a substrate held by the holding apparatus with an energy beam to form a pattern on the substrate.

13. A method of manufacturing an article, the method comprising:
forming a pattern on a substrate using a processing apparatus; and
processing the substrate on which the pattern has been formed,
wherein the processing apparatus includes a holding apparatus for holding the substrate by an electrostatic force,
wherein the holding apparatus includes:
a base including an electrode for generating the electrostatic force;
a plurality of pins provided on the base; and
a seal provided on the base and configured to seal a first space surrounding the plurality of pins,
wherein a cavity and a first hole connecting the cavity and the first space is formed in the base,
wherein a gas is sealed in the first space, the first hole and the cavity in a vacuum by holding the substrate on the pins and the seal by the electrostatic force.

14. A method according to claim 13, wherein the processing apparatus further includes:
a processing chamber in which the pattern is formed on a substrate in a vacuum;
an anterior chamber in which the holding apparatus is caused to hold the substrate to be carried to the processing chamber;
a supply device configured to supply a gas into the anterior chamber; and
a controller configured to control a process for causing the holding apparatus to hold the substrate,
wherein the controller is configured to perform
a first process of supplying the gas into the anterior chamber by the supply device, and
a second process of sealing the gas in the first space, the first hole, and the cavity by holding the substrate on the pins and the seal by the electrostatic force in an atmosphere of the gas.
